(19) United States
(12) Patent Application Publication
(10) Pub. No.: US 2024/0047325 A1
(43) Pub. Date: Feb. 8, 2024

(54) BALL GRID ARRAY AND CONFIGURATION METHOD OF THE SAME

(71) Applicant: REALTEK SEMICONDUCTOR CORP., Hsinchu (TW)

(72) Inventors: CHIN-YUAN LO, HSINCHU (TW); HSIN-HUI LO, HSINCHU (TW)

(21) Appl. No.: 18/210,157

(22) Filed: Jun. 15, 2023

(30) Foreign Application Priority Data
Aug. 3, 2022 (TW) 111129076

(51) Int. Cl. H01L 23/498; H05K 3/34; H01L 23/00

(52) U.S. Cl. CPC H01L 23/49816; H05K 3/3436; H01L 24/16; H01L 2924/15311; H01L 2224/16225; H05K 2201/10734

(57) ABSTRACT

A ball grid array and a configuration method of the same are provided. The ball grid array is formed on a printed circuit board and includes an inner row region and an outer row region. The inner row region includes a plurality of first solder balls that are arranged by a first ball pitch. The first solder balls respectively correspond to a plurality of predetermined vias, and the first ball pitch is determined according to a minimum trace width that is relative to a via size of the predetermined vias. The outer row region surrounds the inner row region and includes a plurality of second solder balls that are arranged by a second ball pitch. The second ball pitch is smaller than the first ball pitch.

### CROSS-REFERENCE TO RELATED PATENT APPLICATION

This application claims the benefit of priority to Taiwan Patent Application No. 111129076, filed on Aug. 3, 2022. The entire content of the above identified application is incorporated herein by reference.

Some references, which may include patents, patent applications and various publications, may be cited and discussed in the description of this disclosure. The citation and/or discussion of such references is provided merely to clarify the description of the present disclosure and is not an admission that any such reference is “prior art” to the disclosure described herein. All references cited and discussed in this specification are incorporated herein by reference in their entireties and to the same extent as if each reference was individually incorporated by reference.

### FIELD OF THE DISCLOSURE

This present disclosure relates to a ball grid array (BGA), and more particularly to a ball grid array and a configuration method of the ball grid array in which solder balls in an inner row region and solder balls in an outer row region can be arranged by different ball pitches.

### BACKGROUND OF THE DISCLOSURE

A ball grid array is a surface-adhesive packaging technology for integrated circuits and includes multiple solder balls. The solder balls are formed on a printed circuit board, and the ball grid array package uses the solder balls as input/output pins.

Conventionally, in order to increase the quantity of input/output pins (i.e., solder balls), a distance (also referred to as a ball pitch) between centers of two adjacent solder balls can be reduced. However, only one ball pitch is used for arrangement of the solder balls in the conventional technology, and for each solder ball in an inner row region (i.e., the region near the center of the printed circuit board) of the ball grid array, the printed circuit board also needs to have space for vias to ensure that the solder balls can be properly used. Therefore, although a smaller ball pitch can increase the quantity of input/output pins, it often results in the printed circuit board not having enough space for vias, and causes poor solder ball utilization rate in the inner row region.

### SUMMARY OF THE DISCLOSURE

In response to the above-referenced technical inadequacies, the present disclosure provides a ball grid array and a configuration method of the ball grid array, in which solder balls in an inner row region and solder balls in an outer row region can be arranged by different ball pitches.

In one aspect, the present disclosure provides a ball grid array. The ball grid array is formed on a printed circuit board. The ball grid array includes an inner row region and an outer row region. The inner row region includes a plurality of first solder balls that are arranged by a first ball pitch. The plurality of first solder balls respectively correspond to a plurality of predetermined vias, and the first ball pitch is determined according to a minimum trace width that is relative to a via size of the plurality of predetermined vias. The outer row region is disposed to surround the inner row region. The outer row region includes a plurality of second solder balls that are arranged by a second ball pitch. The second ball pitch is smaller than the first ball pitch.

In another aspect, the present disclosure provides a configuration method of a ball grid array. The configuration method includes the following steps. Firstly, disposing a plurality of first solder balls that are arranged by a first ball pitch on a printed circuit board so as to form an inner row region. The plurality of first solder balls respectively correspond to a plurality of predetermined vias, and the first ball pitch is determined according to a minimum trace width that is relative to a via size of the plurality of predetermined vias. Secondly, disposing a plurality of second solder balls that are arranged by a second ball pitch on the printed circuit board to surround the inner row region to form an outer row region. The second ball pitch is smaller than the first ball pitch.

Therefore, one of the advantages of the ball grid array and the configuration method of the ball grid array provided by the present disclosure is that, the solder balls in the inner row region can be arranged by a larger ball pitch so as to increase a utilization rate of the solder balls in the inner row region, and the solder balls in the outer row region can be arranged by a smaller ball pitch so as to satisfy requirements for increasing the quantity of pins.

These and other aspects of the present disclosure will become apparent from the following description of the embodiment taken in conjunction with the following drawings and their captions, although variations and modifications therein may be affected without departing from the spirit and scope of the novel concepts of the disclosure.

### BRIEF DESCRIPTION OF THE DRAWINGS

The described embodiments may be better understood by reference to the following description and the accompanying drawings, in which:

FIG. 1 is a schematic view of a ball grid array according to the present disclosure;

FIG. 2 is a partially enlarged view of an inner row region of FIG. 1;

FIG. 3 is a partially enlarged view of an outer row region of FIG. 1; and

FIG. 4 is a flowchart of steps of a configuration method of the ball grid array according to the present disclosure.

### DETAILED DESCRIPTION OF THE EXEMPLARY EMBODIMENTS

The present disclosure is more particularly described in the following examples that are intended as illustrative only since numerous modifications and variations therein will be apparent to those skilled in the art. Like numbers in the drawings indicate like components throughout the views. As used in the description herein and throughout the claims that follow, unless the context clearly dictates otherwise, the meaning of “a”, “an”, and “the” includes plural reference, and the meaning of “in” includes “in” and “on”. Titles or subtitles can be used herein for the convenience of a reader, which shall have no influence on the scope of the present disclosure.

The terms used herein generally have their ordinary meanings in the art. In the case of conflict, the present document, including any definitions given herein, will prevail. The same thing can be expressed in more than one way. Alternative language and synonyms can be used for any term(s) discussed herein, and no special significance is to be placed upon whether a term is elaborated or discussed herein. A recital of one or more synonyms does not exclude the use of other synonyms. The use of examples anywhere in this specification including examples of any terms is illustrative only, and in no way limits the scope and meaning of the present disclosure or of any exemplified term. Likewise, the present disclosure is not limited to various embodiments given herein. Numbering terms such as “first”, “second” or “third” can be used to describe various components, signals or the like, which are for distinguishing one component/signal from another one only, and are not intended to, nor should be construed to impose any substantive limitations on the components, signals or the like.

### First Embodiment

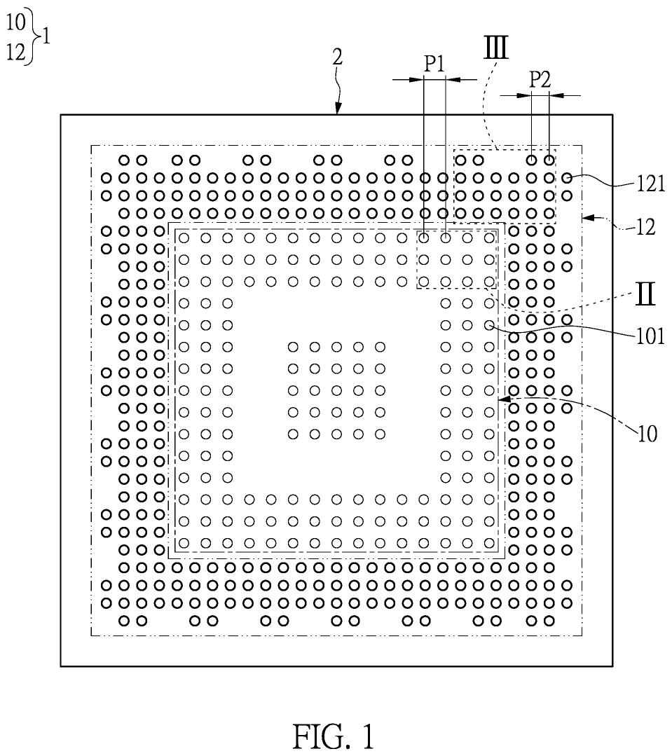

Referring to FIG. 1, the present disclosure provides a ball grid array 1 that is formed on a printed circuit board 2. The ball grid array 1 includes an inner row region 10 and an outer row region 12. The inner row region 10 is one region of the ball grid array 1 adjacent to a center of the printed circuit board 2, and the outer row region 12 is another region of the ball grid array 1 adjacent to edges of the printed circuit board 2. It should be noted that, patterns of the inner row region 10 and the outer row region 12 as depicted in the FIG. 1 are only provided as an example, and a specific pattern and a number of rows of solder balls of the inner row region 10 and the outer row region 12 are not limited in the present disclosure.

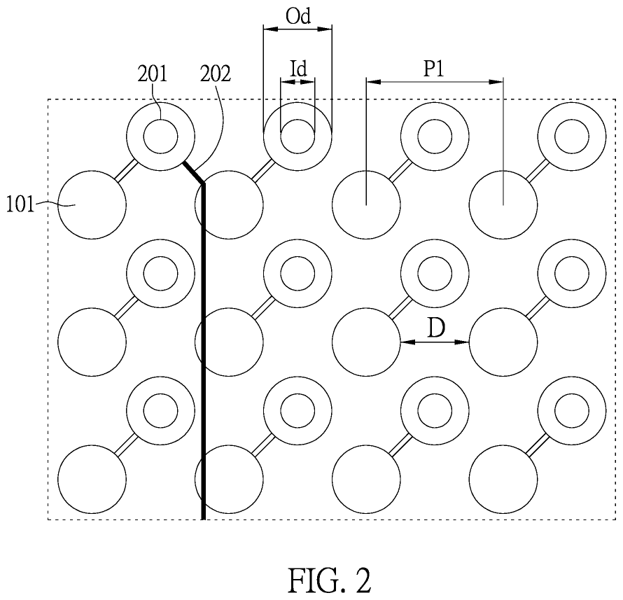

As shown in FIG. 1, the inner row region 10 includes a plurality of first solder balls 101 that are arranged by a first ball pitch P1. However, referring to FIG. 2, for each of the first solder balls 101 of the inner row region 10, the printed circuit board 2 further requires spaces for arranging vias, so as to ensure that the first solder ball 101 is properly utilized, and a via size is limited in a manufacturing process of a printed circuit board that with a lower cost. Therefore, in order to optimize the space utilization under the aforementioned conditions, the first solder balls 101 of embodiments of the present disclosure can respectively correspond to a plurality of predetermined vias 201, and the first ball pitch P1 is determined according to a minimum trace width D that is relative to a via size of the plurality of predetermined vias 201.

Specifically, each of the first solder balls 101 is connected to a corresponding signal wire 202 through a corresponding one of the predetermined vias 201. For sake of clarity, only one of the first solder balls 101 being connected to a corresponding signal wire 202 through a corresponding one of the predetermined vias 201 is depicted in FIG. 2. However, a specific position and a wiring path of the predetermined via 201 and the signal wire 202 corresponding to each of the first solder balls 101 are not limited in the present disclosure. In this embodiment, an inner diameter Id and an outer diameter Od of the via size can respectively be 0.2 mm and 0.4 mm, but the present disclosure is not limited thereto. In short, as shown in FIG. 2, the minimum trace width D is a minimum distance between two adjacent ones of the plurality of first solder balls 101, and the minimum trace width D is relative to the via size and arrangement positions of the plurality of predetermined vias 201. Furthermore, the first ball pitch P1 is greater than or equal to the minimum trace width D plus a size of each of the first solder balls 101 (i.e., a diameter of the first solder ball 101).

In other words, for the first ball pitch P1, the size of each of the first solder balls 101 can be considered in addition to the minimum trace width D, but the size of each of the first solder balls 101 is not limited in the present disclosure. Because the first solder balls 101 respectively correspond to the plurality of predetermined vias 201 in the present disclosure, and the first ball pitch P1 is determined by the minimum trace width D that is related to the via size of the predetermined vias 201, the inner row region 10 of the ball grid array can be used to prevent an issue of having insufficient space for arranging vias on the printed circuit board 2. Furthermore, the first solder balls 101 that are arranged by the first ball pitch P1 can be properly utilized, thereby increasing a utilization rate of the solder balls at the inner row region 10.

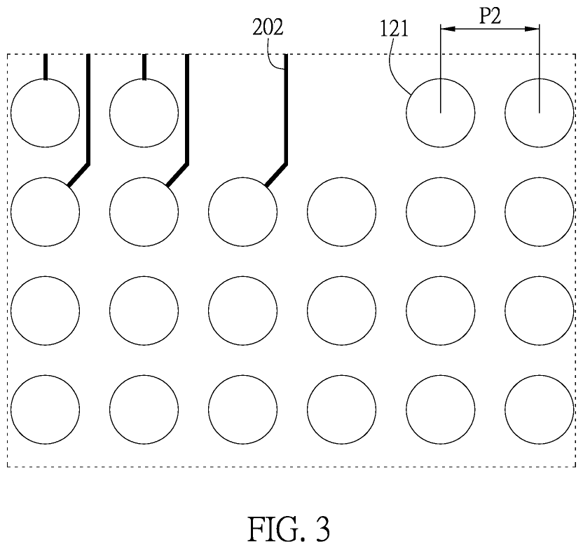

Furthermore, the outer row region 12 is disposed to surround the inner row region 10. The outer row region 12 includes a plurality of second solder balls 121 that are arranged by a second ball pitch P2, and the second ball pitch P2 is smaller than the first ball pitch P1. Reference is made to FIG. 3, because each of the second solder balls 121 can be directly connected to the corresponding signal wire 202 without any vias, the second ball pitch P2 can be smaller than the first ball pitch P1 in the present disclosure. For example, the first ball pitch P1 is 0.8 mm, and the second ball pitch P2 is 0.65 mm, so that in a same unit size as shown in FIG. 2 and FIG. 3, a quantity of the second solder balls 121 arranged by the second ball pitch P2 is greater than a quantity of the first solder balls 101 arranged by the first ball pitch P1, so that a requirement of increasing the quantity of pins can be met. For the sake of clarity, only a small number of the second solder balls 121 being connected to corresponding signal wires 202 are depicted in FIG. 3. In addition, a practical wiring path of the corresponding signal wires 202 of each of the second solder balls 121 is not limited in the present disclosure.

On the other hand, reference is made to Table 1. Based on a manufacturing process of a printed circuit board having a lower cost and a larger via size, Table 1 shows a relationship between an area and a solder ball quantity of the first solder balls 101 of the inner row region 10 being respectively arranged by the first ball pitch P1 of 0.8 mm and 0.65 mm. As shown in Table 1, when the first ball pitch P1 is 0.8 mm and an area of the inner row region 10 is 5.1552 mm², the solder ball quantity can be 15; however, when the first ball pitch P1 is 0.65 mm and an area of the inner row region 10 is 6.3375 mm², the solder ball quantity is decreased to be 12.

TABLE 1

| | First ball pitch P1 | 0.8 mm | 0.65 mm |
|---|---|---|---|
| Inner row | Area (mm²) | 5.1552 | 6.3375 |
| region 10 | Solder ball quantity | 15 | 12 |

Therefore, when a space utilization rate is defined as a solder ball quantity in a unit area, for the inner row region 10, the space utilization rate is 2.91 when the first solder balls 101 are arranged by a pitch of 0.8 mm, and the space utilization rate is only 1.89 when the first solder balls 101 are arranged by 0.65 mm. Therefore, based on a manufacturing process of a printed circuit board having a lower cost and a larger via size, the first ball pitch P1 of 0.8 mm is more conducive to an optimized space utilization rate than the first ball pitch P1 of 0.65 mm, but the present disclosure is not limited thereto. In other embodiments, the first ball pitch P1 can be 0.75 mm, and the second ball pitch P2 can be 0.65 mm. A practical via size is also not limited in the present disclosure. That is, based on a manufacturing process of a printed circuit board having a lower cost and a larger via size, a ball pitch that allows an optimized space utilization rate in the inner row region 10 is preferred as the first ball pitch P1 in the embodiments of the present disclosure.

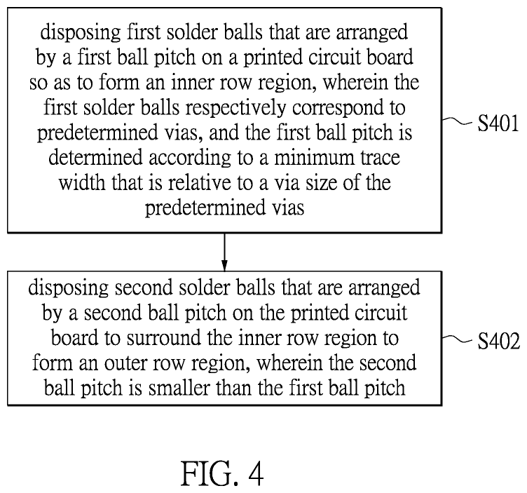

Referring to FIG. 4, the present disclosure provides a configuration method of a ball grid array 1. The configuration method includes steps S401 and S402. In step S401, the plurality of first solder balls 101 are arranged by the first ball pitch P1 on the printed circuit board 2 so as to form the inner row region 10. The plurality of first solder balls 101 respectively correspond to the plurality of predetermined vias 201, and the first ball pitch P1 is determined according to the minimum trace width D that is relative to the via size of the plurality of predetermined vias 201. Then, in step S402, the plurality of second solder balls 121 that are arranged by the second ball pitch P2 are disposed on the printed circuit board 2 to surround the inner row region 10 to form an outer row region 12. The second ball pitch P2 is smaller than the first ball pitch P1.

Furthermore, the inner row region 10 can be one region of the ball grid array 1 adjacent to the center of the printed circuit board 2, and the outer row region 12 is another region of the ball grid array 1 adjacent to the edges of the printed circuit board 2. However, a specific pattern and a number of rows of solder balls of the inner row region 10 and the outer row region 12 are not limited in the present disclosure. In addition, because the first solder balls 101 respectively correspond to the plurality of predetermined vias 201 in the present disclosure, and the first ball pitch P1 is determined by the minimum trace width D that is related to the via size of the predetermined vias 201, the inner row region 10 of the ball grid array can be used to prevent an issue of having insufficient space for arranging vias on the printed circuit board 2. Furthermore, the first solder balls 101 that are arranged by the first ball pitch P1 can be properly utilized, thereby increasing a utilization rate of the solder balls at the inner row region 10.

### Beneficial Effects of the Embodiments

In conclusion, one of the advantages of the ball grid array and the configuration method of the ball grid array provided by the present disclosure is that, the solder balls in the inner row region can be arranged by a larger ball pitch so as to increase a utilization rate of the solder balls in the inner row region, and the solder balls in the outer row region can be arranged by a smaller ball pitch so as to satisfy requirements for increasing the quantity of pins. In addition, based on a manufacturing process of a printed circuit board having a lower cost and a larger via size, a space utilization rate in the inner row region can be optimized.

The foregoing description of the exemplary embodiments of the disclosure has been presented only for the purposes of illustration and description and is not intended to be exhaustive or to limit the disclosure to the precise forms disclosed. Many modifications and variations are possible in light of the above teaching.

The embodiments were chosen and described in order to explain the principles of the disclosure and their practical application so as to enable others skilled in the art to utilize the disclosure and various embodiments and with various modifications as are suited to the particular use contemplated. Alternative embodiments will become apparent to those skilled in the art to which the present disclosure pertains without departing from its spirit and scope.

What is claimed is:

1. A ball grid array, formed on a printed circuit board, comprising:
an inner row region including a plurality of first solder balls that are arranged by a first ball pitch, wherein the plurality of first solder balls respectively correspond to a plurality of predetermined vias, and the first ball pitch is determined according to a minimum trace width that is relative to a via size of the plurality of predetermined vias; and
an outer row region being disposed to surround the inner row region, wherein the outer row region includes a plurality of second solder balls that are arranged by a second ball pitch, and wherein the second ball pitch is smaller than the first ball pitch.

2. The ball grid array according to claim 1, wherein the minimum trace width is a minimum distance between two adjacent ones of the plurality of first solder balls.

3. The ball grid array according to claim 1, wherein the first ball pitch is 0.8 mm or 0.75 mm.

4. The ball grid array according to claim 3, wherein the second ball pitch is 0.65 mm.

5. The ball grid array according to claim 1, wherein the inner row region is one region of the ball grid array adjacent to a center of the printed circuit board, and the outer row region is another region of the ball grid array adjacent to edges of the printed circuit board.

6. A configuration method of a ball grid array, comprising:
disposing a plurality of first solder balls that are arranged by a first ball pitch on a printed circuit board so as to form an inner row region, wherein the plurality of first solder balls respectively correspond to a plurality of predetermined vias, and the first ball pitch is determined according to a minimum trace width that is relative to a via size of the plurality of predetermined vias; and
disposing a plurality of second solder balls that are arranged by a second ball pitch on the printed circuit board to surround the inner row region to form an outer row region, wherein the second ball pitch is smaller than the first ball pitch.

7. The configuration method according to claim 6, wherein the minimum trace width is a minimum distance between two adjacent ones of the plurality of first solder balls.

8. The configuration method according to claim 6, wherein the first ball pitch is 0.8 mm or 0.75 mm.

9. The configuration method according to claim 8, wherein the second ball pitch is 0.65 mm.

10. The configuration method according to claim 6, wherein the inner row region is one region of the ball grid array adjacent to a center of the printed circuit board, and the outer row region is another region of the ball grid array adjacent to edges of the printed circuit board.
